(19) United States
(12) Patent Application Publication
(10) Pub. No.: US 2012/0193763 A1
(43) Pub. Date: Aug. 2, 2012

(54) METHOD OF MANUFACTURING SEMICONDUCTOR DEVICE, SEMICONDUCTOR DEVICE AND RESIST COATER

(75) Inventor: Atsumi YAMAGUCHI, Kanagawa (JP)

(73) Assignee: Renesas Electronics Corporation

(21) Appl. No.: 13/348,407

(22) Filed: Jan. 11, 2012

(30) Foreign Application Priority Data
Jan. 28, 2011 (JP) 2011-016518

(51) Int. Cl. H01L 21/31; B02C 23/00; H01L 29/06

(52) U.S. Cl. 257/618; 438/703; 241/39; 257/E21.24; 257/E29.022

(57) ABSTRACT

To provide a method of manufacturing a semiconductor device with reduced generation of humps, a semiconductor device with reduced generation of humps, and a resist coater. An inactive liquid such as pure water is discharged at a predetermined pressure from a nozzle for discharging fluid for processing hump while spinning the semiconductor substrate to spray a region where a hump is generated. The hump is crushed by spraying the inactive liquid at a high pressure onto the hump, and the film thickness of the bottom-layer resist becomes almost uniform across the entire semiconductor substrate.

### CROSS-REFERENCE TO RELATED APPLICATIONS

The disclosure of Japanese Patent Application No. 2011-16518 filed on Jan. 28, 2011 including the specification, drawings and abstract is incorporated herein by reference in its entirety.

### BACKGROUND

The present invention relates to a method of manufacturing a semiconductor device, a semiconductor device and a resist coater, and in particular to a method of manufacturing a semiconductor device to which a multilayer resist system is applied, a semiconductor device manufactured by a method of manufacturing the same, and a resist coater applied to the method of manufacturing the same.

When a semiconductor device including a semiconductor integrated circuit is manufactured, a selective treatment (process) such as an ion implantation process in a predetermined region in a semiconductor substrate and an etching process on a processed film formed over the surface of the semiconductor substrate is performed. Such processes involve performing lithography for forming a pattern of a composition, a so-called photosensitive photoresist coating (photoresist film), which is exposed to an active light beam such as an ultraviolet ray, X-ray, electron beam on the processed film for the purpose of selectively protecting the processed film and the like. In this lithography, in particular, pattern formation by a photoresist film using an ultraviolet ray is most widely used.

With greater integration of semiconductor integrated circuits and higher performance, finer circuit patterns and greater control over their sizes are required. In exposure equipments, wavelengths of exposure light sources have been increasingly shortened, from the g-line (wavelength=436 nm) and i-line (wavelength=365 nm) of mercury lamps to KrF excimer laser (wavelength=248 nm) and ArF excimer laser (wavelength=193 nm). Moreover, in recent years, an immersion exposure technique which can improve the resolving power by filling the space between a reduction projection lens of an aligner (exposure equipment) and a photoresist film applied over a semiconductor substrate with water (pure water) has been developed, leading to longer lives of optical lithographs.

Meanwhile, in photoresist films, the film thicknesses of the photoresist films have been increasingly reduced to ensure resolution of patterns, and photoresist films having film thicknesses of about 100 nm are applied recently. However, because of finer patterns and reduced thickness of photoresist films, ensuring etching resistance of films to be worked is becoming difficult in lithography to which antireflection layer such as organic BARC (Bottom Anti Reflection Coating) and photoresist are applied. Examples of films to be processed include various types of films such as silicon oxide films and polysilicon films.

In order to ensure such etching resistance, the multilayer resist system has been increasingly introduced recently. A typical example of the multilayer resist system is a tri-layer resist system. In the tri-layer resist system, a top-layer resist film, a middle-layer resist film and a bottom-layer resist film are formed. The top-layer resist film is a resist film over which a pattern is formed by exposure and development, and is a photosensitive resist film. The bottom-layer resist film is a resist film which serves as a mask in dry etching on the processed film. The middle-layer resist film is a resist film which transfers the pattern of the top-layer resist film onto the bottom-layer resist film.

In order to render the bottom-layer resist film a dry-etched mask, a material having high etching resistance and functionality of antireflection and leveling unevenness in the underlayer is used as a material of the bottom-layer resist film. Moreover, in order to impart etch selectivity to the middle-layer resist film relative to the top resist and bottom resist, a material containing silicon (Si) atoms at a high concentration is used as a material of the middle-layer resist film. By employing such a multilayer resist system, high etching resistance (etch selectivity) is ensured, allowing accurately forming fine patterns. An example of documents which disclose multilayer resist system is patent document 1.

### Related-Art Documents

### [Patent Documents]

[Patent document 1]

Japanese Examined Patent Publication No. Hei 04 (1992)-30740

[Patent document 2]

Japanese Unexamined Patent Publication No. 2010-93049

### SUMMARY

However, multilayer resist system has the problems as described below in the bottom-layer resist film or middle-layer resist film. In the step for forming the bottom-layer resist film or middle-layer resist film, first, a predetermined bottom-layer (middle-layer) resist is applied over the surface of the wafer (semiconductor substrate). A bottom-layer (middle-layer) resist having a uniform film thickness is formed over the wafer by spinning the wafer at a predetermined number of rotations. Edge rinse is performed by spraying a portion of the bottom-layer (middle-layer) resist positioned on the edge of the wafer with a predetermined organic solvent which dissolves the bottom-layer (middle-layer) resist while spinning the wafer. Thereafter, the bottom-layer (middle-layer) resist film is formed to allow the bottom-layer (middle-layer) resist to undergo crosslinking by carrying out a bake process at a predetermined temperature.

In a step for performing edge rinse among this series of steps for forming the bottom-layer (middle-layer) resist film, the bottom-layer (middle-layer) resist positioned at the outer periphery of the wafer is dissolved. The dissolved bottom-layer (middle-layer) resist spins off to the outside from the spinning wafer. In contrast, a portion of the bottom-layer (middle-layer) resist dissolved but left on the wafer without spinning off may swell and bulge during drying of the bottom-layer (middle-layer) resist. Therefore, the film thickness of the portion of the bottom-layer (middle-layer) resist positioned at the outermost periphery becomes thicker than that in the portion of the bottom-layer (middle-layer) resist film positioned thereinside. This bulging portion of the bottom-layer (middle-layer) resist is referred to as “hump”.

When a process such as etching is performed on the processed film in the state that a hump is generated on the bottom-layer (middle-layer) resist film, resist residues of the bottom-layer resist film or middle-layer resist film may occur. Moreover, residues of the processed film (processed film residues) may occur. These residues lead to generation of foreign substances (particles). An example of documents disclosing the phenomenon of generation of humps and the problems caused by the generation of humps is patent document 2.

The present invention has been made to solve the above problems, and an object of the same is to provide a method of manufacturing a semiconductor device which achieves reduced generation of humps. Another object of the same is to provide a semiconductor device with reduced generation of humps manufactured by such a method of manufacturing a semiconductor device. Still another object of the same is to provide a resist coater for use in such a method of manufacturing a semiconductor device.

The method of manufacturing a semiconductor device according to an example of the present invention includes the following steps: A processed film which is subjected to a predetermined process is formed over a main face of a semiconductor substrate. A first resist film which serves as a mask material when the processed film is processed is formed in a manner of covering the processed film. A second resist film for performing patterning by using the first resist film as the mask material is formed in a manner of covering the first resist film. A predetermined resist pattern is formed by performing a predetermined photolithographic process (prebake, exposure and development) on the second resist film. A mask material is formed by etching the first resist film by using the resist pattern as a mask. A predetermined process is performed on the processed film by using the mask material (first resist film) as a mask. In particular, the step of forming the first resist film includes the following steps: A resist material film is formed by applying a predetermined resist material having etching resistance to processing of the processed film onto the surface of the processed film. A portion of the resist material film positioned at the outer periphery of the semiconductor substrate is removed by spraying the outer periphery with an organic solvent while spinning the semiconductor substrate. The semiconductor substrate with the portion of the resist material removed positioned on its outer periphery is dried. The outer periphery of the resist material film left on the semiconductor substrate is sprayed with at least one fluid selected from predetermined liquids and gases for crushing the resist material film while spinning the semiconductor substrate. A heat treatment is performed on the resist material film.

The semiconductor device according to another Example of the present invention is a semiconductor device manufactured by the above method of manufacturing a semiconductor device.

The resist coater according to still another Example of the present invention includes a spin chuck, a fluid feed section, and a fluid discharge nozzle. The spin chuck rotatably retains the semiconductor substrate. The fluid feed section serves as a source of a predetermined fluid for crushing the resist material film formed over the surface of the semiconductor substrate. The fluid discharge nozzle is coupled to the fluid feed section, and discharges and sprays the predetermined fluid toward a portion positioned at the outer periphery of the semiconductor substrate of the resist material film formed over the surface of the semiconductor substrate in a state that the semiconductor substrate is retained on the spin chuck.

According to the method of manufacturing a semiconductor device according to an Example of the present invention, resist residues or residues of films to be processed are reduced. As a result, a reduction in the yield of the semiconductor device caused by the generation of foreign substances can be suppressed. Moreover, a reduction in reliability of the semiconductor device caused by peeling of films can be also suppressed.

According of another Example of the present invention, lowered yield or reliability of the semiconductor device is suppressed.

According to the resist coater of still another Example of the present invention, resist residues or residues of films to be processed can be reduced.

### BRIEF DESCRIPTION OF THE DRAWINGS

FIG. 1 is a cross-sectional view which shows a step in the method of manufacturing a semiconductor device according to First Embodiment of the present invention.

FIG. 2 is a cross-sectional view which shows the step carried out after the step shown in FIG. 1 in the embodiment.

FIG. 3 is a cross-sectional view which shows the step carried out after the step shown in FIG. 2 in the embodiment.

FIG. 4 is a cross-sectional view which shows the step carried out after the step shown in FIG. 3 in the embodiment.

FIG. 5 is a cross-sectional view which shows the step carried out after the step shown in FIG. 4 in the embodiment.

FIG. 6 is a cross-sectional view which shows the step carried out after the step shown in FIG. 5 in the embodiment.

FIG. 7 is a cross-sectional view which shows the step carried out after the step shown in FIG. 6 in the embodiment.

FIG. 8 is a cross-sectional view which shows the step carried out after the step shown in FIG. 7 in the embodiment.

FIG. 9 is a cross-sectional view which shows the step carried out after the step shown in FIG. 8 in the embodiment.

FIG. 10 is a cross-sectional view which shows the step carried out after the step shown in FIG. 9 in the embodiment.

FIG. 11 is a cross-sectional view which shows the step carried out after the step shown in FIG. 10 in the embodiment.

FIG. 12 is a cross-sectional view which shows the step carried out after the step shown in FIG. 11 in the embodiment.

FIG. 13 is a cross-sectional view which shows the step carried out after the step shown in FIG. 12 in the embodiment.

FIG. 14 is a cross-sectional view which shows the step carried out after the step shown in FIG. 13 in the embodiment.

FIG. 15 is a cross-sectional view which shows the step carried out after the step shown in FIG. 14 in the embodiment.

FIG. 16 is a cross-sectional view which shows the step carried out after the step shown in FIG. 15 in the embodiment.

FIG. 17 is a cross-sectional view which shows the step carried out after the step shown in FIG. 16 in the embodiment.

FIG. 18 is a cross-sectional view which shows the step carried out after the step shown in FIG. 17 in the embodiment.

FIG. 19 is a cross-sectional view which shows the step carried out after the step shown in FIG. 18 in the embodiment.

FIG. 20 is a cross-sectional view which shows the step carried out after the step shown in FIG. 19 in the embodiment.

FIG. 21 is a cross-sectional view which shows the step carried out after the step shown in FIG. 20 in the embodiment.

FIG. 22 is a cross-sectional view which shows the step carried out after the step shown in FIG. 21 in the embodiment.

FIG. 23 is a cross-sectional view which shows the step carried out after the step shown in FIG. 22 in the embodiment.

FIG. 24 is a cross-sectional view which shows the step carried out after the step shown in FIG. 23 in the embodiment.

FIG. 25 is a cross-sectional view which shows the step carried out after the step shown in FIG. 24 in the embodiment.

FIG. 26 is a cross-sectional view which indicates a step of the method of manufacturing a semiconductor device according to a Comparative Example.

FIG. 27 is a cross-sectional view which shows the step carried out after the step shown in FIG. 26.

FIG. 28 is a cross-sectional view which shows the step carried out after the step shown in FIG. 27.

FIG. 29 is a cross-sectional view which shows the step carried out after the step shown in FIG. 28.

FIG. 30 is a cross-sectional view which shows the step carried out after the step shown in FIG. 29.

FIG. 31 is a cross-sectional view which shows the step carried out after the step shown in FIG. 30.

FIG. 32 is a cross-sectional view which shows the step carried out after the step shown in FIG. 31.

FIG. 33 is a cross-sectional view which shows the step carried out after the step shown in FIG. 32.

FIG. 34 is a cross-sectional view which shows the step carried out after the step shown in FIG. 33.

FIG. 35 is a cross-sectional view which shows the step carried out after the step shown in FIG. 34.

FIG. 36 is a cross-sectional view which shows the step carried out after the step shown in FIG. 35.

FIG. 37 is a cross-sectional view which shows a step the method of manufacturing a semiconductor device according to a first variant in the embodiment.

FIG. 38 is a cross-sectional view which shows a step the method of manufacturing a semiconductor device according to a second variant in the embodiment.

FIG. 39 is a cross-sectional view which shows a step the method of manufacturing a semiconductor device according to a third variant in the embodiment.

FIG. 40 is a cross-sectional view which shows a step the method of manufacturing a semiconductor device according to a fourth variant in the embodiment.

FIG. 41 is a cross-sectional view which shows a step the method of manufacturing a semiconductor device according to a fifth variant in the embodiment.

FIG. 42 is a block diagram which shows the concept of the resist coater according to Second Embodiment of the present invention.

FIG. 43 is a cross-sectional view which shows a step the method of manufacturing a semiconductor device according to Third Embodiment of the present invention.

FIG. 44 is a cross-sectional view which shows the step carried out after the step shown in FIG. 43 in the embodiment.

FIG. 45 is a cross-sectional view which shows the step carried out after the step shown in FIG. 44 in the embodiment.

FIG. 46 is a cross-sectional view which shows the step carried out after the step shown in FIG. 45 in the embodiment.

FIG. 47 is a cross-sectional view which shows the step carried out after the step shown in FIG. 46 in the embodiment.

FIG. 48 is a cross-sectional view which shows the step carried out after the step shown in FIG. 47 in the embodiment.

FIG. 49 is a cross-sectional view which shows the step carried out after the step shown in FIG. 48 in the embodiment.

FIG. 50 is a cross-sectional view which shows the step carried out after the step shown in FIG. 49 in the embodiment.

FIG. 51 is a cross-sectional view which shows the step carried out after the step shown in FIG. 50 in the embodiment.

FIG. 52 is a cross-sectional view which shows the step carried out after the step shown in FIG. 51 in the embodiment.

### DETAILED DESCRIPTION

### First Embodiment

Principal parts of the method of manufacturing a semiconductor device to which a multilayer resist system is applied will be described herein. A tri-layer resist system involving a bottom-layer resist film, a middle-layer resist film and a top-layer resist film is taken as an example of the multilayer resist system.

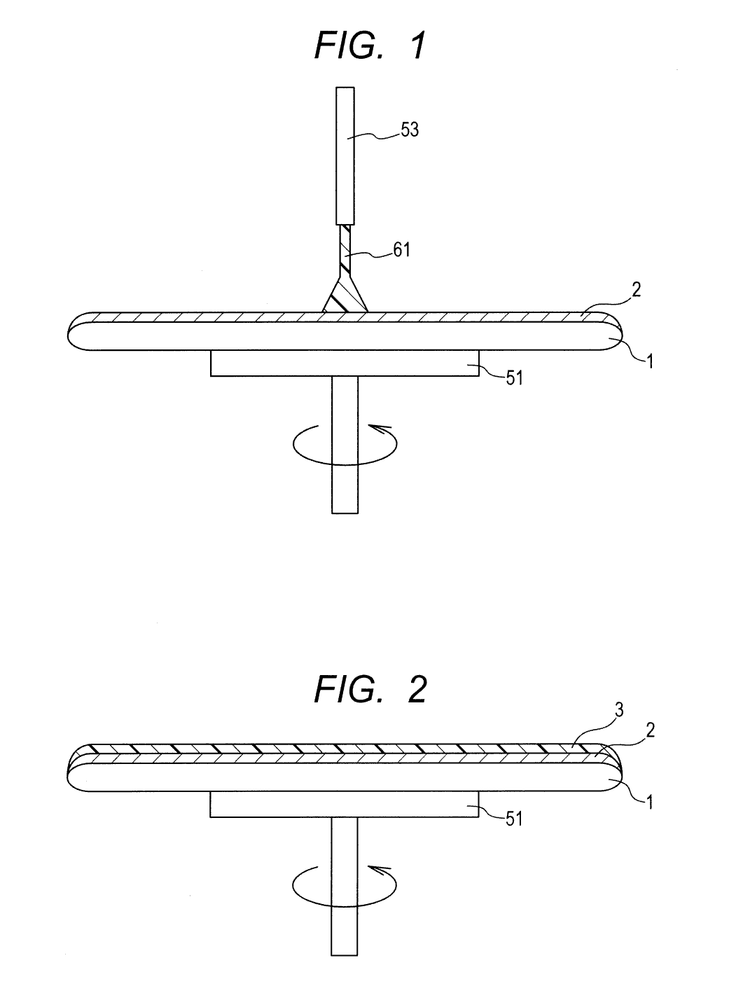

First, the bottom-layer resist film is formed over the surface of the processed film. As shown in FIG. 1, a semiconductor substrate 1 on which a processed film 2 to be subjected to a predetermined process is formed is retained on a spin chuck 51 of the resist coater. For example, a silicon oxide film, a polysilicon film or the like is formed as the processed film 2. A predetermined amount of a bottom-layer resist liquid 61 is fed in the form of drops from a resist discharge nozzle 53 on the surface of the semiconductor substrate 1 (on the surface of the processed film 2). Second, as shown in FIG. 2, the spin chuck 51 is spun at a predetermined number of rotations in a state that the semiconductor substrate 1 is retained, whereby an unwanted portion of the bottom-layer resist liquid spins off the semiconductor substrate 1, and a bottom-layer resist 3 having a uniform film thickness is formed over the surface of the semiconductor substrate 1.

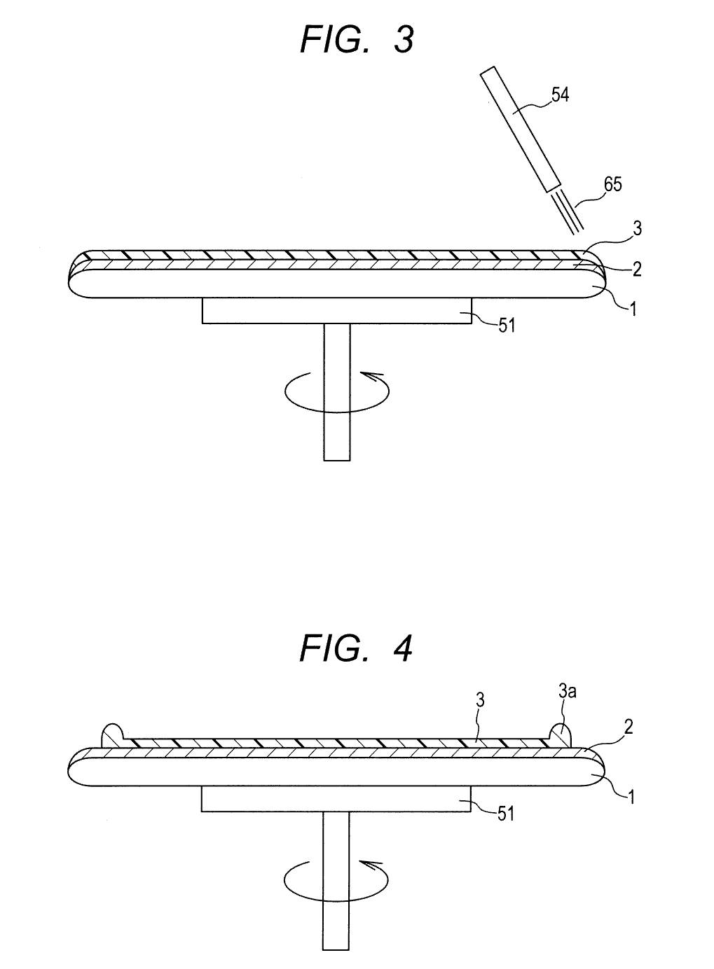

Second, as shown in FIG. 3, while the semiconductor substrate 1 is spun, a solvent 65 which dissolves the bottom-layer resist 3 is discharged and sprayed onto the bottom-layer resist 3 from a solvent discharge nozzle 54 to perform edge rinse. Edge rinse is normally performed on a region ranging from 1 mm to 3 mm from the periphery of the semiconductor substrate. Components of the dissolved bottom-layer resist spin off the semiconductor substrate outwardly.

In contrast, the components of the dissolved bottom-layer resist left on the semiconductor substrate 1 without spinning off swell and bulge when the bottom-layer resist 3 is dried, and as shown in FIG. 4, a hump 3a may occur at the outer periphery of the bottom-layer resist 3.

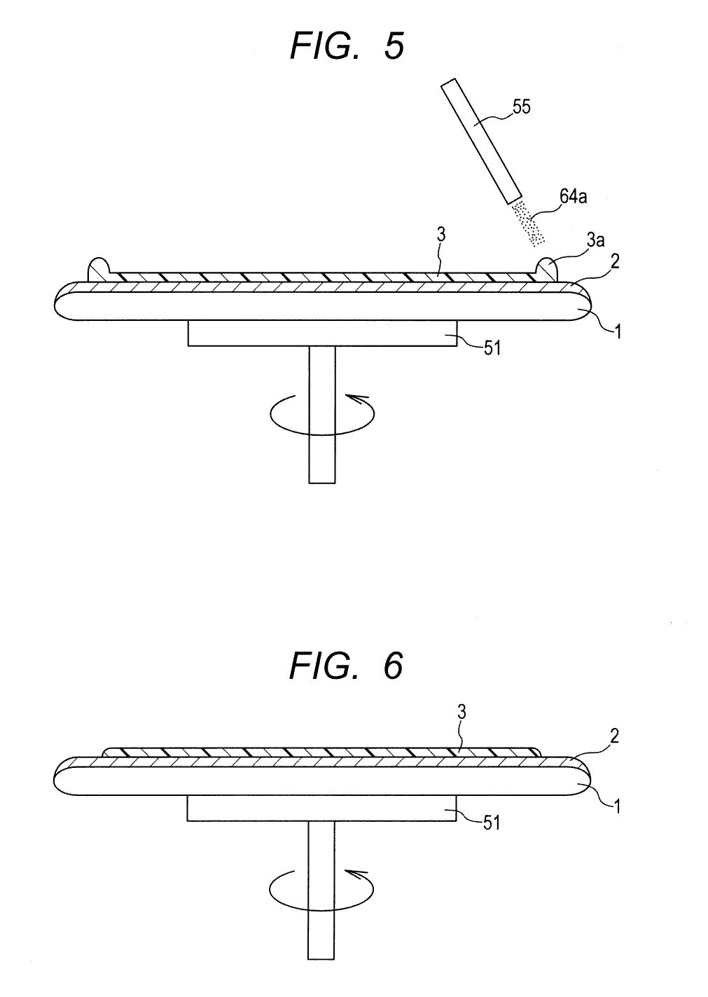

Subsequently, as shown in FIG. 5, while the semiconductor substrate 1 is spun, an inactive liquid 64a, for example, pure water, is discharged at a predetermined pressure from a nozzle for discharging fluid for processing hump 55, and is sprayed onto a region where the hump 3a is generated. As shown in FIG. 6, the hump 3a is crushed by spraying the inactive liquid 64a at a high pressure onto the hump 3a, and the film thickness of the bottom-layer resist 3 becomes almost uniform across the entire semiconductor substrate 1.

At this time, by setting the temperature of the inactive liquid 64a, for example, to a temperature of about 100° C., the resist material film layer 3 onto which the inactive liquid 64a is sprayed is softened, so that the hump 3a can be effectively crushed. Thus, this technique does not remove humps, but crushes and flattens humps.

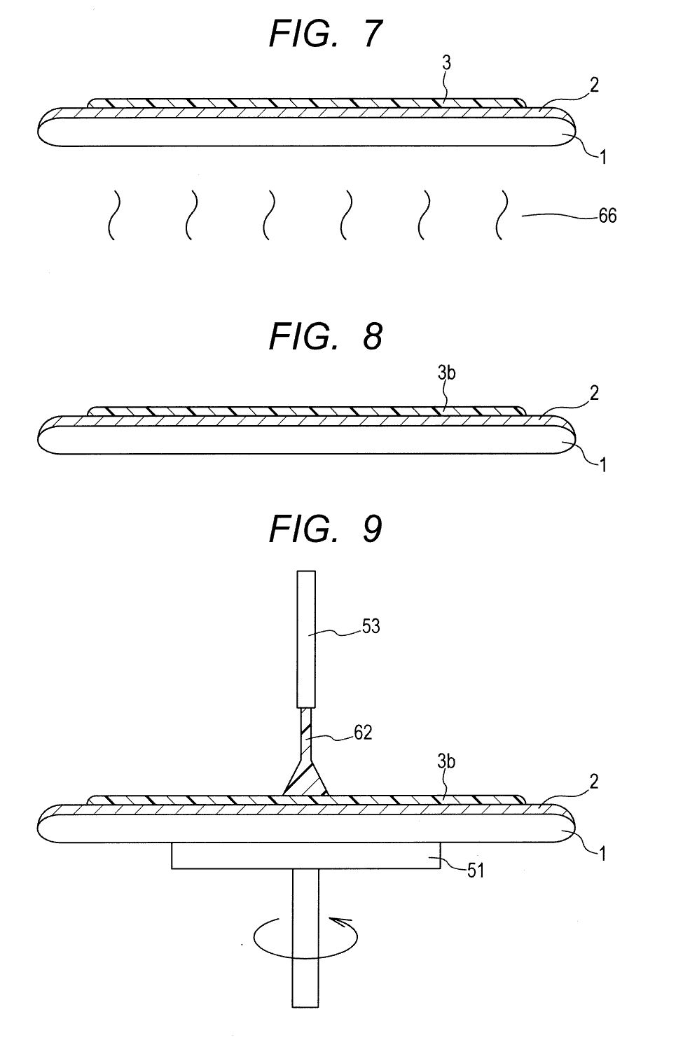

Next, as shown in FIG. 7, a bake process 66 is performed on the semiconductor substrate 1 at a predetermined temperature, whereby the bottom-layer resist 3 is allowed to undergo crosslinking, and as shown in FIG. 8, a bottom-layer resist film 3b which serves as a mask material in patterning the processed film 2 is formed.

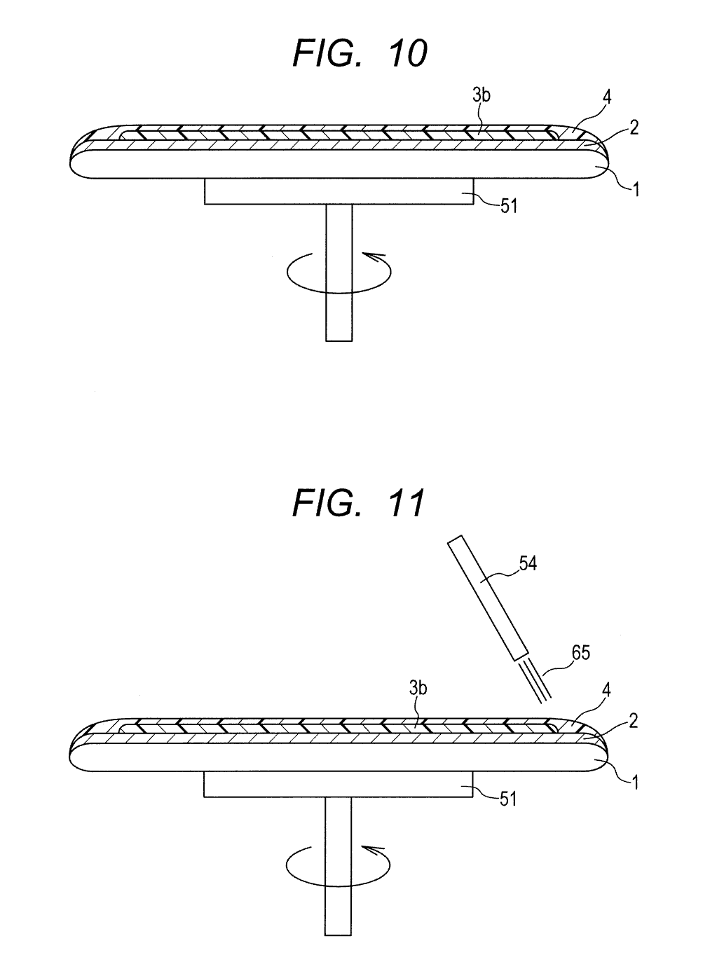

Subsequently, a middle-layer resist film is formed. As shown in FIG. 9, a predetermined amount of a middle-layer resist liquid 62 is fed in the form of drops on the surface of the semiconductor substrate 1 from the resist discharge nozzle 53. Subsequently, as shown in FIG. 10, the spin chuck 51 is spun at a predetermined number of rotations in a state that the semiconductor substrate 1 is retained, whereby an unwanted portion middle-layer resist liquid spins off the semiconductor substrate 1, and a middle-layer resist 4 having a uniform film thickness is formed over the surface of the semiconductor substrate 1.

Subsequently, as shown in FIG. 11, edge rinse is carried out by discharging and spraying a solvent 65 which dissolves the middle-layer resist 4 onto the middle-layer resist 4 from the solvent discharge nozzle 54 while the semiconductor substrate 1 is spun. Components of the middle-layer resist dissolved spinoff the semiconductor substrate outwardly. The solvent 65 which dissolves the middle-layer resist 4 may be of a different type than the solvent which dissolves the bottom-layer resist 3.

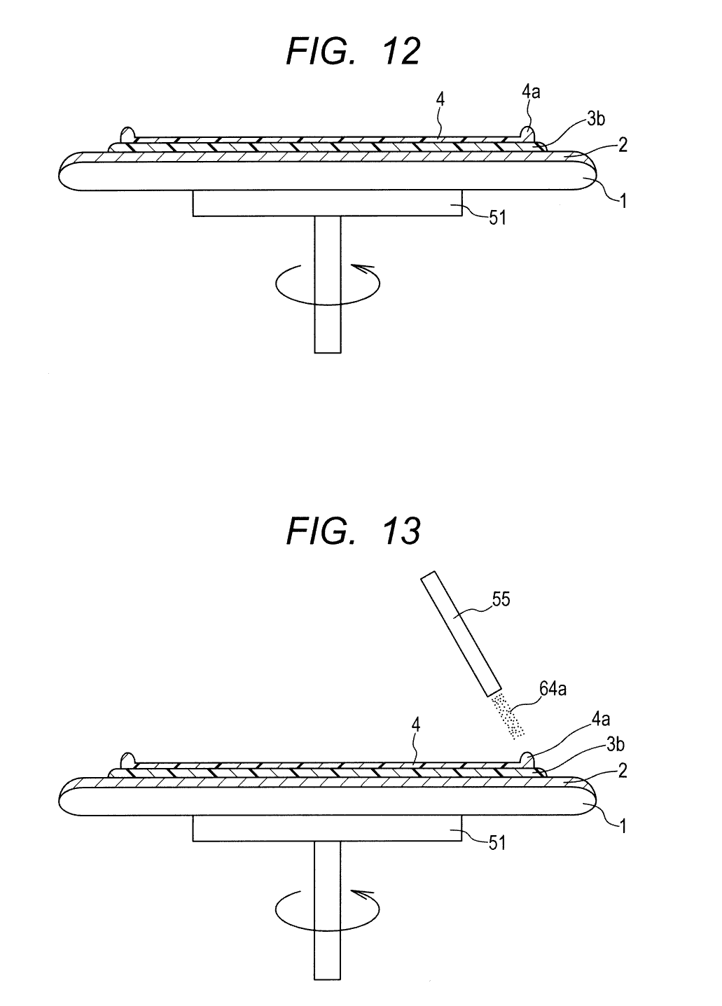

In contrast, components of the middle-layer resist dissolved but left on the semiconductor substrate 1 without spinning off swell and bulge when the middle-layer resist 4 is dried, and as shown in FIG. 12, a hump 4a may occur at the outer periphery of the middle-layer resist 4.

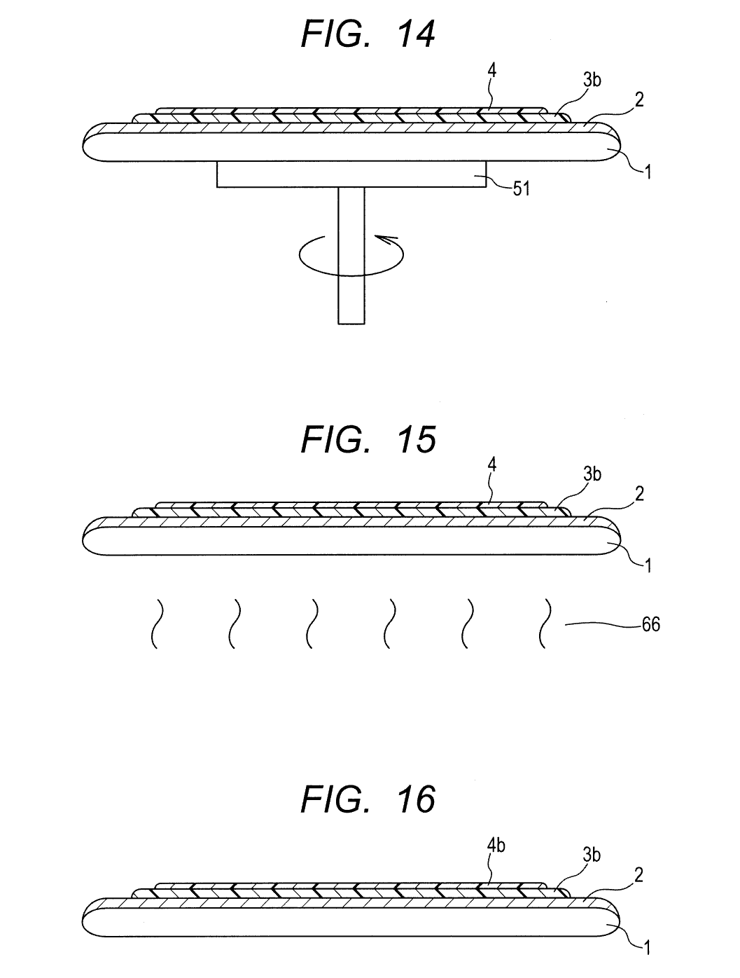

Subsequently, as shown in FIG. 13, the inactive liquid 64a, for example, pure water, is discharged at a predetermined pressure from the nozzle for discharging fluid for processing hump 55 while the semiconductor substrate 1 is spun, and is sprayed onto a region where the hump 4a is generated. By spraying the inactive liquid 64a onto the hump 4a at a high pressure, as shown in FIG. 14, the hump 4a is crushed, and the film thickness of the middle-layer resist 4 becomes almost uniform across the entire semiconductor substrate 1.

At this time, by setting the temperature of the inactive liquid 64a, for example, to about 100° C., the middle-layer resist 4 is sprayed with the inactive liquid 64a and softened, and therefore the hump 4a can be effectively crushed.

Subsequently, as shown in FIG. 15, a bake process 66 is performed on the semiconductor substrate 1 at a predetermined temperature, whereby the middle-layer resist 4 is allowed to undergo crosslinking, and as shown in FIG. 16, the middle-layer resist film 4b which serves as a mask material in patterning the processed film 2 is formed.

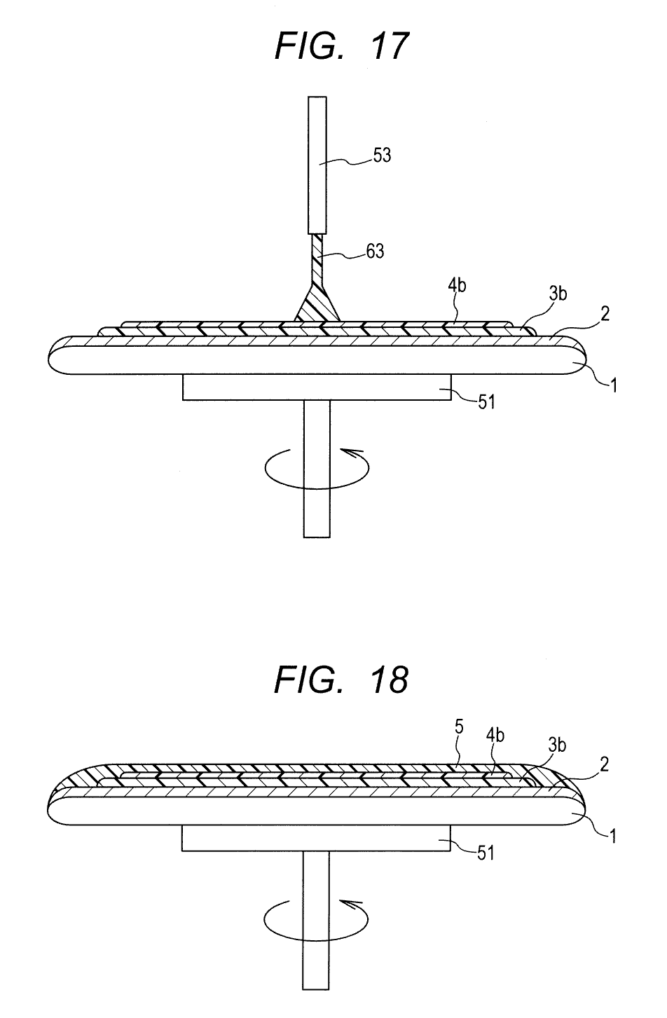

Subsequently, a top-layer resist film is formed. As shown in FIG. 17, a predetermined amount of a top resist solution 63 is supplied in the form of drops from the resist discharge nozzle 53 on the surface of the semiconductor substrate 1. The top resist solution contains a material having photosensitivity. Subsequently, as shown in FIG. 18, the spin chuck 51 is spun at a predetermined number of rotations in a state that the semiconductor substrate 1 is retained, whereby an unwanted portion of the top resist solution spins off the semiconductor substrate 1, and a top-layer resist 5 having a uniform film thickness is formed on the surface of the semiconductor substrate 1.

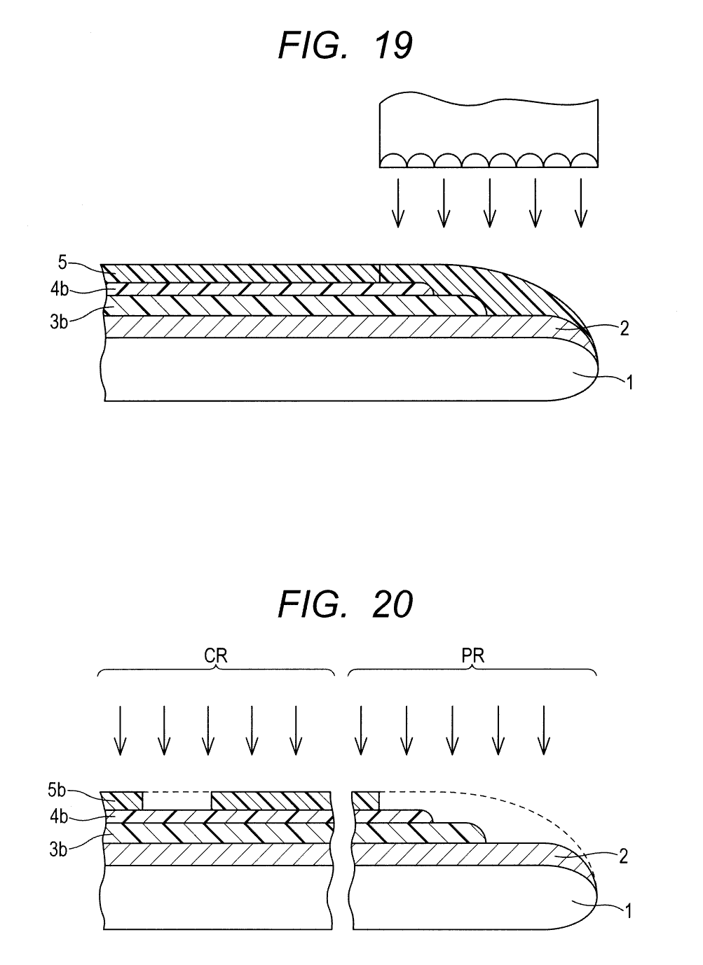

Subsequently, by subjecting the top-layer resist 5 to a predetermined photolithographic process (prebake, exposure and development), a predetermined pattern of the top-layer resist (not shown) is formed in a region where chips are formed. Subsequently, as shown in FIG. 19, a peripheral exposure process is performed at the outer periphery of the semiconductor substrate 1.

Subsequently, a bake process is performed on the top-layer resist film 5b which has been subjected to the photolithographic process and the like. Thereafter, as shown in FIG. 20, a predetermined pattern is formed on the top-layer resist film 5b in a chip formation region CR by performing a development process. In contrast, at the outer periphery PR of the semiconductor substrate, the portion of the top-layer resist film 5b is removed, and the surface of the outer periphery of the bottom-layer resist film 3b and the surface of the outer periphery of the middle-layer resist film 4b where the hump is crushed and flattened are appeared. Thus, as shown in FIG. 21, the bottom-layer resist film 3b, middle-layer resist film 4b and top-layer resist film 5b for patterning the processed film 2 are formed.

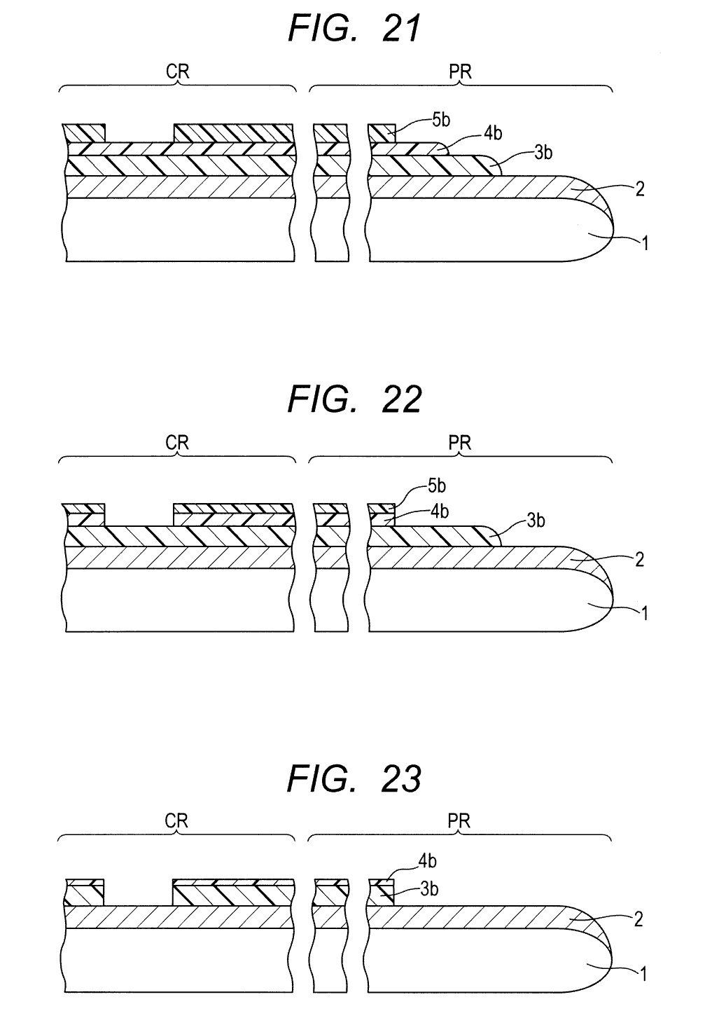

Subsequently, the processed film 2 is patterned by the bottom-layer resist film 3b, middle-layer resist film 4b and top-layer resist film 5b. First, as shown in FIG. 22, an etching process is performed on the middle-layer resist film 4b using the top-layer resist film 5b as a mask so that the pattern of the top-layer resist film 5b is transferred onto the middle-layer resist film 4b. In this case, a material containing the element silicon (Si) is applied as an intermediate resist layer material. For example, etching is performed by using a fluorine-based gas such as CF₄, whereby high etch selectivity with respect to the top-layer resist film 5b can be obtained.

Subsequently, as shown in FIG. 23, etching is performed on the bottom-layer resist film 3b by using the middle-layer resist film 4b as a mask, whereby the pattern on the top-layer resist film 5b is transferred onto the bottom-layer resist film 3b via the middle-layer resist film 4b. In this case, for example, by performing etching using a gas such as oxygen (0₂) or nitrogen (N₂)/hydrogen (H₂), high etch selectivity with respect to the middle-layer resist film 4b can be obtained.

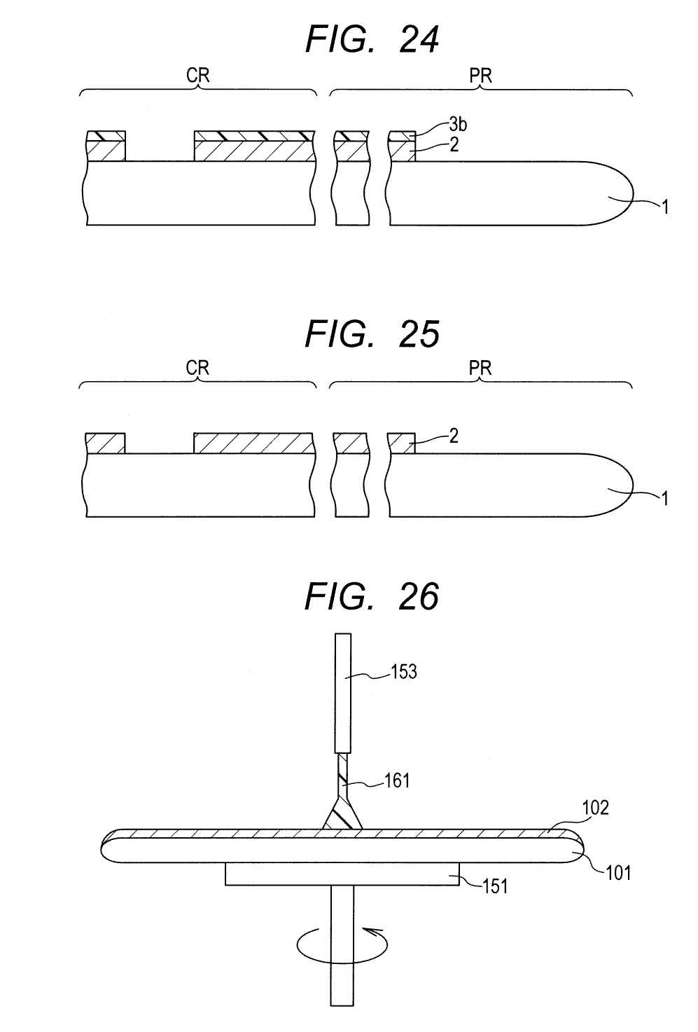

Subsequently, as shown in FIG. 24, the processed film 2 is patterned by performing etching on the processed film 2 using the bottom-layer resist film 3b as a mask. Thereafter, as shown in FIG. 25, the bottom-layer resist film 3b and the like remaining on the semiconductor substrate 1 are removed by performing an oxygen plasma asking process, finishing patterning of the processed film 2.

In the method of manufacturing a semiconductor device mentioned above, the humps 3a, 4a generated on the bottom-layer resist 3 or the middle-layer resist 4 are crushed and flattened by a liquid at a high pressure, whereby residues of resists and films to be processed can be reduced. This will be described with reference to Comparative Examples.

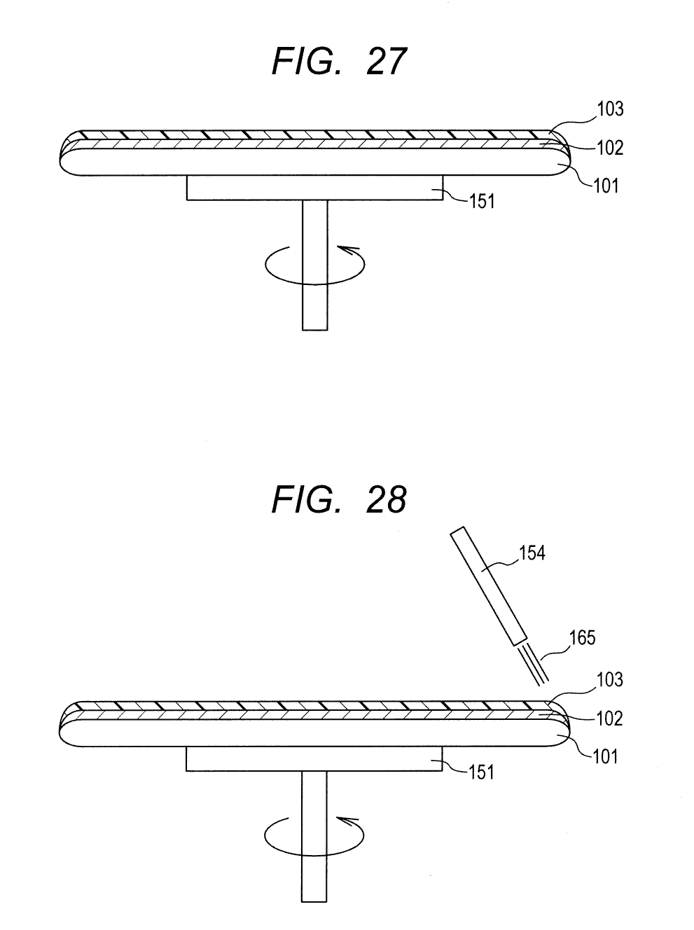

In the method of manufacturing a semiconductor device according to Comparative Example, first, as shown in FIG. 26, a processed film 102 is formed, and a bottom resist material 161 is fed in the form of drops from a resist discharge nozzle 153 onto the surface of a semiconductor substrate 101 retained on a spin chuck 151. Subsequently, as shown in FIG. 27, a bottom-layer resist 103 having a uniform film thickness is formed on the surface of the semiconductor substrate 1 by spinning the semiconductor substrate 101.

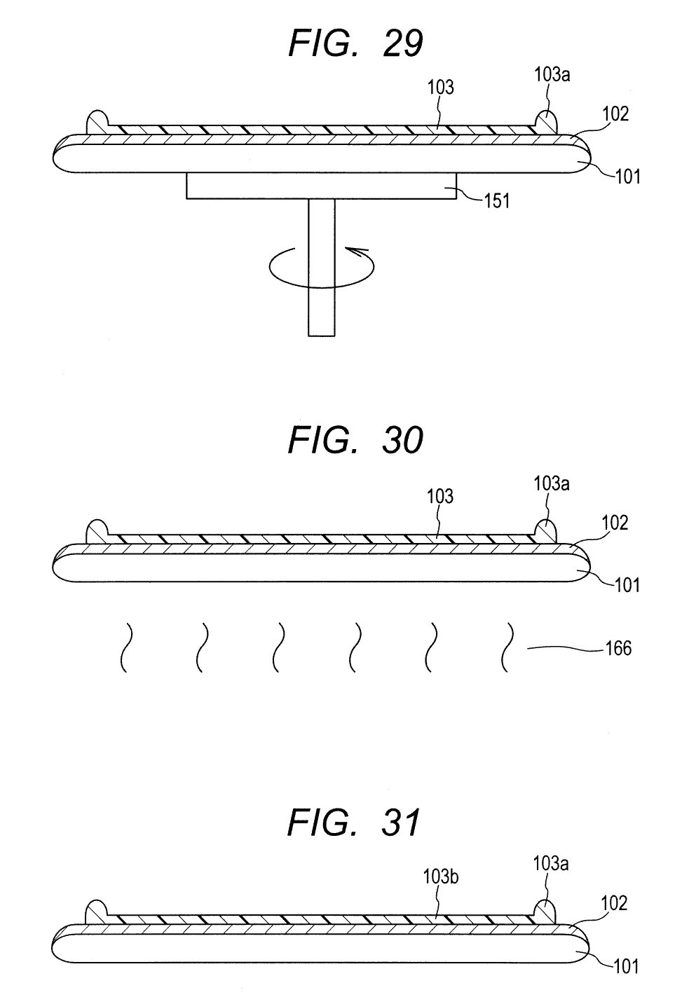

Subsequently, as shown in FIG. 28, edge rinse is performed by discharging a solvent 165 from a solvent discharge nozzle 154 and by spraying the same onto a bottom-layer resist 103. Subsequently, the bottom-layer resist 103 is dried. At this time, as shown in FIG. 29, components of the bottom-layer resist dissolved and left on the semiconductor substrate 101 may swell and bulge, generating a hump 103a. Subsequently, as shown in FIG. 30, a bake process 166 is performed on the semiconductor substrate 101 at a predetermined temperature so that the bottom-layer resist 103 is allowed to undergo crosslinking, and as shown in FIG. 31, a bottom-layer resist film 103b is formed.

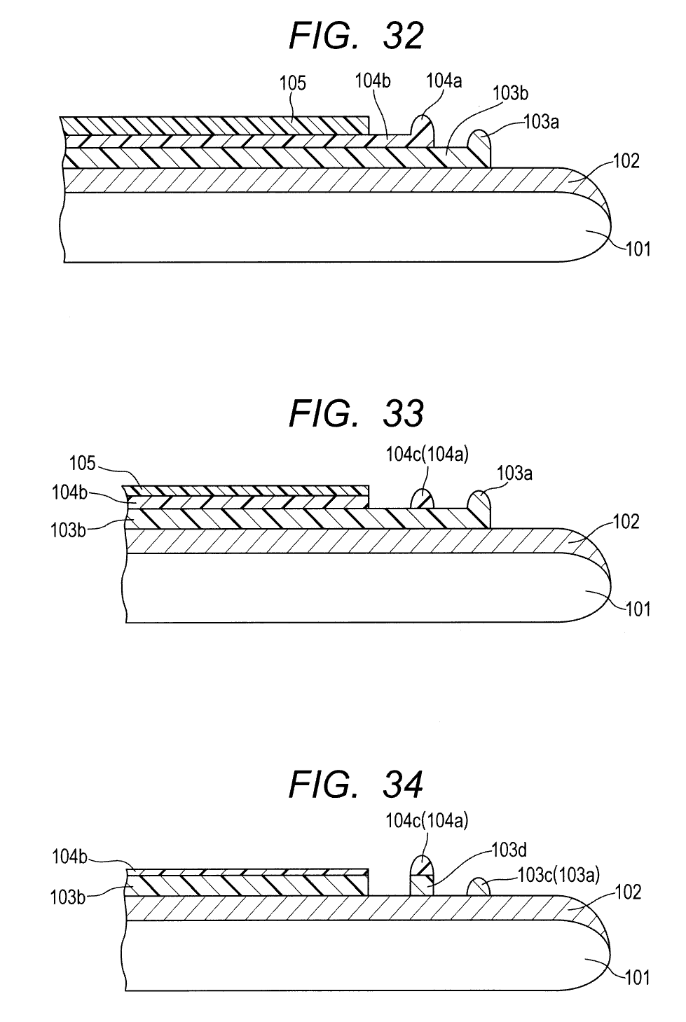

Subsequently, a middle-layer resist liquid is provided on the surface of the semiconductor substrate 101 in the form of drops, and a middle-layer resist film 104b is formed by performing a step similar to the step for forming the bottom-layer resist film. Humps 104a may be generated when the intermediate resist layer material layer is dried on the middle-layer resist film 104b (refer to FIG. 32). Subsequently, a top resist solution is fed in the form of drops onto the surface of the semiconductor substrate 101, the top-layer resist film 105 is formed by performing a step similar to the step (FIG. 17, etc.) which forms the top-layer resist film in the embodiment mentioned above. In such a manner, as shown in FIG. 32, the bottom-layer resist film 103b, middle-layer resist film 104b and top-layer resist film 105 for patterning the processed film 102 are formed. Humps 103a, 104a are found on the bottom-layer resist film 103b or middle-layer resist film 104b appeared at the outer periphery of the semiconductor substrate 101.

Subsequently, the processed film 102 is patterned by the bottom-layer resist film 103b, middle-layer resist film 104b and top-layer resist film 105. First, as shown in FIG. 33, an etching process is performed on the middle-layer resist film 104b using the top-layer resist film 105b as a mask, whereby the pattern of the top-layer resist film 105b is transferred onto the middle-layer resist film 104b. At this time, the middle-layer resist film 104b has high etch selectivity with respect to the top-layer resist film 5b, and therefore the portion of the middle-layer resist film 104b in an area where the humps 104a are generated is often converted into a resist residue 104c. Moreover, the hump 103a of the bottom-layer resist film 103b is often left unetched.

Subsequently, as shown in FIG. 34, etching is performed on the bottom-layer resist film 103b using the middle-layer resist film 104b as a mask, whereby the pattern of the top-layer resist film 105b via the middle-layer resist film 104b is transferred onto the bottom-layer resist film 103b. At this time, since the bottom-layer resist film 103b has high etch selectivity with respect to the middle-layer resist film 104b, the portion of the bottom-layer resist film 103b in the area where the hump 103a is generated at the outer periphery of the semiconductor substrate 101, which should be removed down to the bottom-layer resist film 103b originally, is often converted into the resist residue 103c. Moreover, in the portion where the resist residue 104c is located, the resist residue 104c serves as a mask so that the portion of the bottom-layer resist film 103b located immediately below the resist residue may be converted into a resist residue 103d.

Thus, in the method of manufacturing a semiconductor device according to Comparative Example, the resist residues 103c, 103d, 104c are often present at the outer periphery of the semiconductor substrate 101 at the point when the resist mask (bottom-layer resist film 103b, etc.) for patterning the processed film 102 is formed.

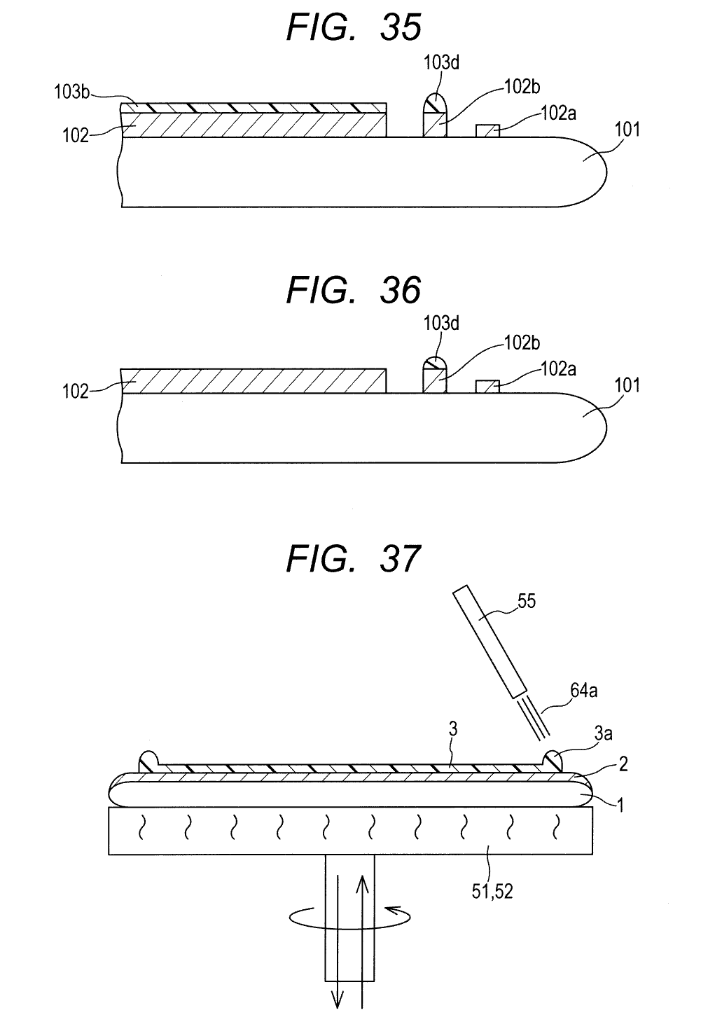

Subsequently, as shown in FIG. 35, etching is performed on the processed film 102 using the bottom-layer resist film 103b and the like as masks, whereby the processed film 102 is patterned. At this time, the resist residues serve as masks in the portion where the resist residues 104c, 103d are located so that the portion of the processed film 102 is converted into a residue of the processed film 102b. Moreover, the portion of the processed film 102 becomes the residue of the processed film 102a also in the portion where the resist residue 103c has been located.

Thereafter, as shown in FIG. 36, the bottom-layer resist film 3b and the like are removed by performing an oxygen plasma asking process. At this time, the resist residue 103d may not be completely removed. Moreover, the residues of the processed film 102a, 102b are not removed either and are left at the outer periphery of the semiconductor substrate 101.

In the method of manufacturing a semiconductor device according to Comparative Example, when a manufacturing process is proceeded in a state that the residues of the processed film 102a, 102b and the like are present at the outer periphery of the semiconductor substrate, the residues of the processed film 102a, 102b and the like may act as foreign substances, which may lower the yield of the semiconductor device. Moreover, the residues may be a cause of peeling of films, leading to lowered reliability of the semiconductor device.

Moreover, when a recycling process (rework process) needs to be performed because of the problems in dimensions and overlay accuracy after the top-layer resist film is patterned, the middle-layer resist film is etched back using a fluorine-based gas, and the bottom-layer resist film is etched back using an oxygen gas. Therefore, in a portion where a hump is generated, it is often the case that the portion of the middle-layer resist film or bottom-layer resist film cannot be completely removed, which may be a cause of generation of foreign substances.

Meanwhile, there are techniques for removing the residues of the processed film 102a, 102b and other substances left at the outer periphery of the semiconductor substrate 101. Bevel etching and bevel CMP (Chemical Mechanical Polishing) are known as such techniques. The residues of the processed film 102a, 102b and other substances are removed by performing this bevel etching and the like after a predetermined etching process and a rework process are performed. However, when these processes are performed, the underlying semiconductor substrate 101 is damaged, which may affect the yield and reliability of the semiconductor device. This creates the necessity to limit the times of the rework process performed.

In contrast, in the method of manufacturing a semiconductor device mentioned above, the humps 3a, 4a generated on the bottom-layer resist film 3b or middle-layer resist film 4b at the outer periphery of the semiconductor substrate are crushed and flattened by spraying a liquid at a high pressure. Accordingly, resist residues and residues of the processed film are reduced at the outer periphery of the semiconductor substrate 1 after the processed film 2 is patterned. This results in suppression of a lowered yield of the semiconductor device caused by the generation of foreign substances. Moreover, lowered reliability of the semiconductor device caused by peeling of the film can be also suppressed.

Moreover, even when a rework process needs to be performed because of the problems in dimensions and overlay accuracy after the top-layer resist film is patterned, all resist films can be completely removed without damaging the underlayer (film, semiconductor substrate, etc.), and a resist pattern can be formed again thereafter. Since no damage to the underlying semiconductor substrate is caused by the rework process, the time of the rework processes performed needs not be limited.

In the method of manufacturing a semiconductor device mentioned above, the case where an inactive liquid (pure water) set at a predetermined temperature is sprayed to crush humps has been described as an example. Herein, variants of the fluid and the like for crushing humps will be described.

Variant 1: The semiconductor substrate may be heated to a predetermined temperature instead of setting an inactive liquid which is sprayed onto humps at a predetermined temperature. In this case, as shown in FIG. 37, the spin chuck 51 which retains the semiconductor substrate 1 may be provided with a heater 52. Also in this case, the bottom-layer resist 3 and the like are softened by setting the temperature of the semiconductor substrate 1 to such a temperature that the bottom-layer resist or middle-layer resist does not undergo crosslinking, and the hump 3a can be readily crushed by spraying a liquid at a high pressure.

The heater 52 may be used to heat the entire semiconductor substrate 1, or to locally heat a portion of the same corresponding to the outer periphery only. In addition, a mechanism for heating the inactive liquid to a predetermined temperature and a mechanism for heating the semiconductor substrate may be used in combination.

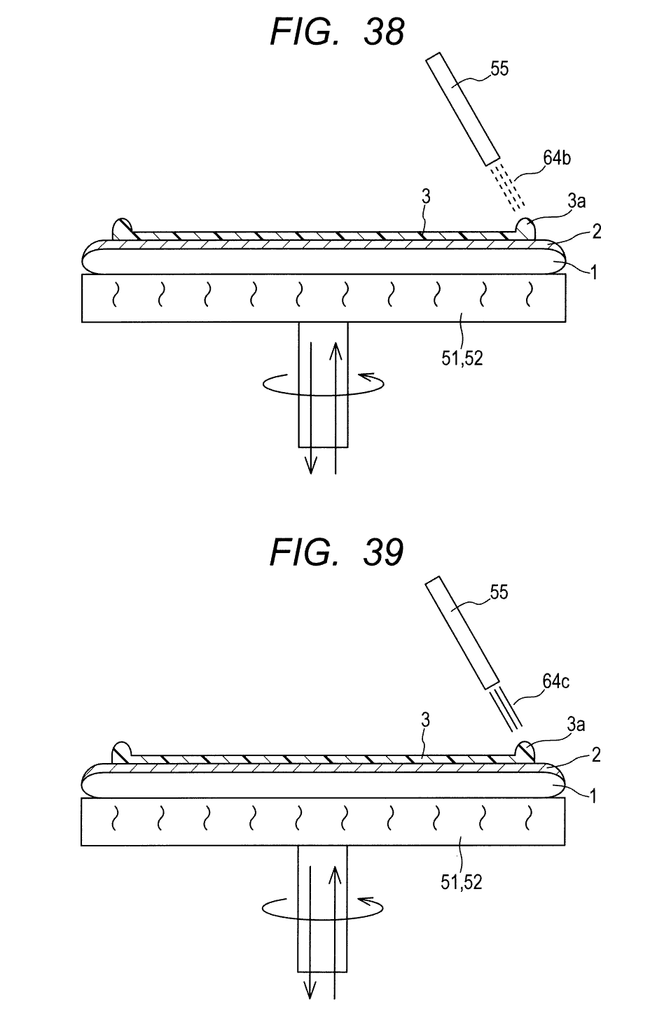

Variant 2: For example, an inactive gas such as a nitrogen gas (N₂) and helium (He) may be used, in place of the inactive liquid (for example, pure water, etc.) as a fluid sprayed onto humps. In this case, as shown in FIG. 38, the hump 3a can be readily crushed by spraying the hump 3a and the like with the inactive gas set at (heated to) a predetermined temperature which does not allow the resist material to undergo crosslinking. Moreover, the heater 52 may be provided on the spin chuck 51 so that the semiconductor substrate 1 is set at a predetermined temperature and the inactive gas is sprayed on to the hump.

Variant 3: A solvent having suitable solubility for the resist material may be used as a fluid which is sprayed onto the hump. In this case, as shown in FIG. 39, for example, a solvent mixture 64c prepared by adding a small amount of a good solvent which exhibits solubility for the bottom-layer resist such as propylene glycol monomethyl ether acetate or cyclohexanone added to a poor solvent which does not exhibit solubility for the bottom-layer resist and the like such as ethyl alcohol or isopropyl alcohol is sprayed onto the hump 3a and the like, whereby the action of chemically dissolving the bottom-layer resist at a low speed is provided in addition to the action of physically crushing the hump by the pressure of the solvent mixture 64c. Therefore, the hump can be flattened more efficiently.

It is preferable that the solubility of the solvent mixture for the resist material is not very high, and the percentage of the good solvent in the solvent mixture is preferably about 5% to about 20%. Moreover, the solvent mixture may be sprayed onto the hump at ambient temperature (room temperature), but the hump can be flattened more effectively by spraying the solvent mixture set (heated) at a predetermined temperature onto the hump. The following configuration may be also employed: the heater 52 is provided on the spin chuck 51; the semiconductor substrate 1 is set at a predetermined temperature; and the solvent mixture is sprayed onto the hump.

Variant 4: The fluid sprayed onto the hump may be an ozone (O₃) -containing gas or ozone water. In this case, as shown in FIG. 40, an ozone-containing gas or ozone water 64d which is capable of degrading organic matters which are components of the bottom-layer resist is sprayed on the hump 3a, whereby the action of degrading a portion of the bottom-layer resist is provided in addition to the action of physically crushing the hump by the pressure of the gas or liquid, and therefore the hump can be flattened more efficiently.

Since ozone has the ability to degrade organic matters which are components of the bottom-layer resist, desired effects can be also obtained by spraying the ozone-containing gas and the like at ambient temperature (room temperature), but the hump can be flattened more effectively by spraying the ozone-containing gas or ozone water set at (heated to) a predetermined temperature. The following configuration may be also employed: the heater 52 is provided on the spin chuck 51; the semiconductor substrate 1 is set at a predetermined temperature; and the ozone-containing gas and the like is sprayed onto the hump.

Variant 5: The fluid sprayed onto the hump maybe inactive solid minute particles may be contained in the inactive gas. Preferable solid minute particles are, for example, minute particles of ice (H₂O) which is applied to an ice scrubber. Minute particles of ice are formed by spraying pure water in the form of a mist by a spray, and cooling the minute particles of the pure water in the form of a mist. The size of ice is determined by the characteristics of the spray, but is normally about 50 μm, and about 5 μm at the smallest. In contrast, the height of the hump is about a few hundred times (a few hundred nm to about 1 μm) the film thickness of the resist material film applied, and the width (the length of the semiconductor substrate in the radial direction) in a region the hump is generated is about 5 μm to about 10 μm.

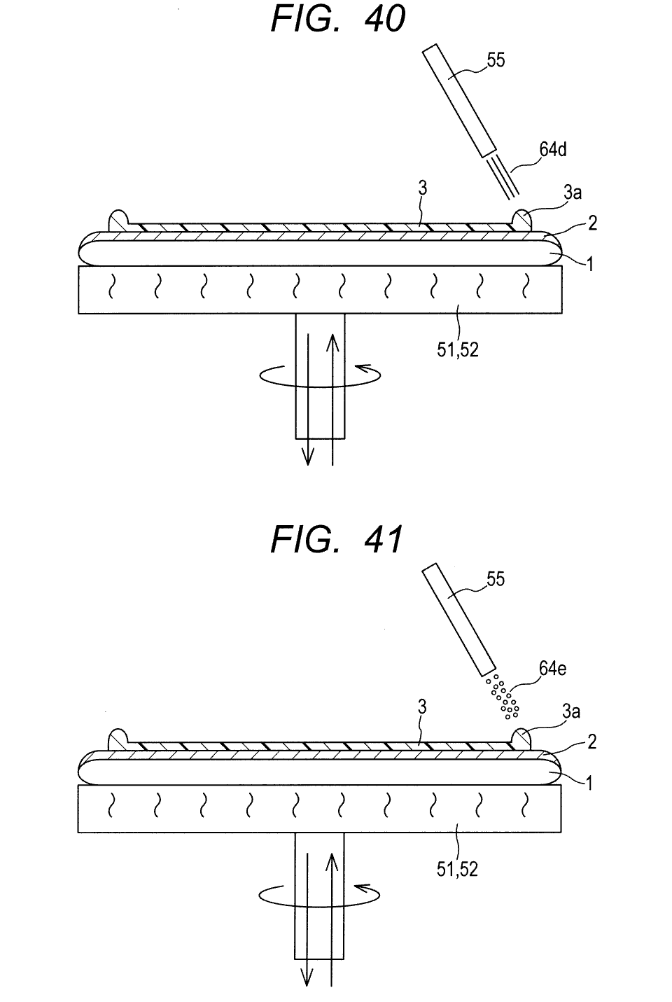

Accordingly, in this case, as shown in FIG. 41, by spraying minute particles of ice 64e with a size of about 5 μm as minute particles of ice onto the hump 3a along with an inert gas, physical impact can be effectively applied on the hump, and the hump can be crushed and flattened efficiently. The following configuration can be also employed: the spin chuck 51 is provided with the heater 52; the semiconductor substrate 1 is set at a predetermined temperature; and the minute particles of ice are sprayed onto the hump in a state that the bottom-layer resist and the like are softened. Examples of inactive minute particles applied include, in addition to minute particles of ice, solid minute particles of argon (Ar), nitrogen (N₂), dry ice (CO₂) and the like.

### Second Embodiment

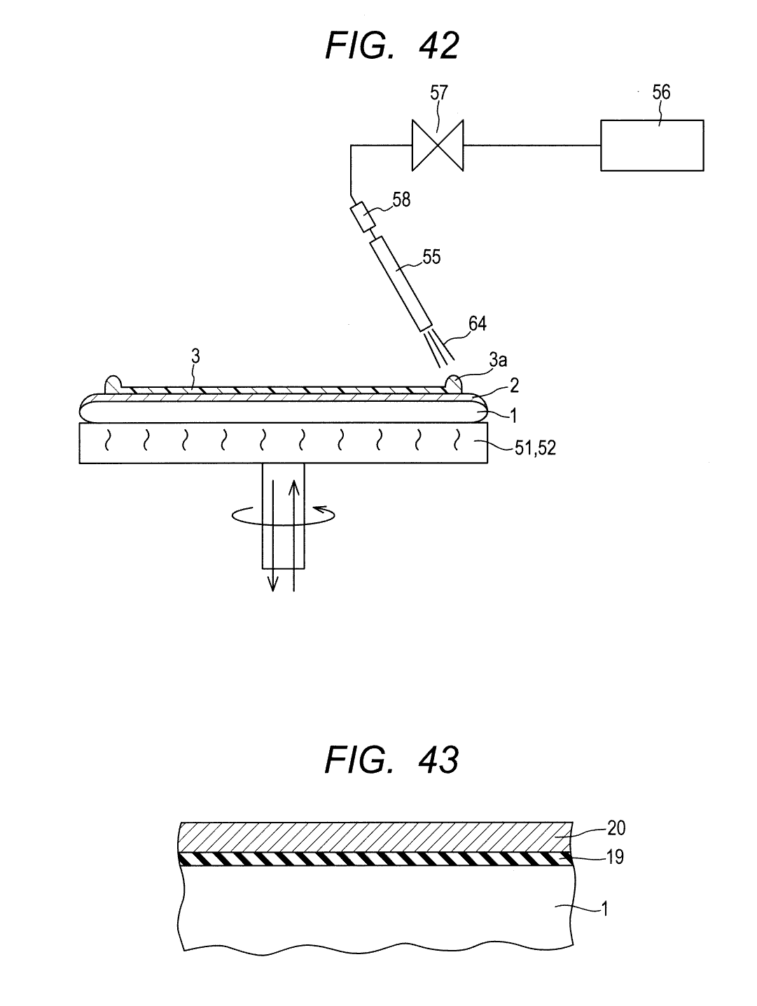

An example of the resist coater which is applied to a multilayer resist system will be described herein. As shown in FIG. 42, this resist coater has, in addition to the spin chuck 51 on which the semiconductor substrate 1 is mounted, a nozzle for discharging fluid for processing hump 55, which sprays the fluid at a high pressure onto the hump, a fluid feed section 56 which is the source of the fluid, and a control valve 57. Moreover, in order to spray the fluid at a high pressure in a state that the bottom-layer (middle-layer) resist is softened, the heater 52 may be provided inside the spin chuck 51, or a fluid heater 58 for heating the fluid itself to be discharged to a predetermined temperature may be provided. The resist coater is normally provided with a resist solution discharge pipe for discharging a resist solution, and a rinse discharge pipe for discharging a rinse, but these discharge pipes are omitted for simplification in FIG. 42.

The fluid feed section 56, as already described, serves as a source of an inactive liquid such as pure water, an inactive gas such as nitrogen or helium, a solvent mixture prepared by adding a good solvent to a poor solvent, an ozone-containing gas, ozone water, or an inactive gas and the like containing minute particles of ice. A fluid such as an inactive liquid fed from the fluid feed section 56 is discharged from the nozzle for discharging fluid for processing hump 55 by the opening and closing operation of the control valve 57 and sprayed onto the hump 3a and the like. The hump 3a is crushed and flattened by the impact force generated by the inactive liquid and the like sprayed onto the hump 3a.

### Third Embodiment

A more specific Example of the method of manufacturing a semiconductor device employing the multilayer resist system will be described herein. First, as shown in FIG. 43, an insulation film 19 is formed by performing a heat oxidation process on the surface of the semiconductor substrate 1. A conductive film 20 containing, for example, a polysilicon film and a metal silicide film of the same and the like is formed on the insulation film 19.

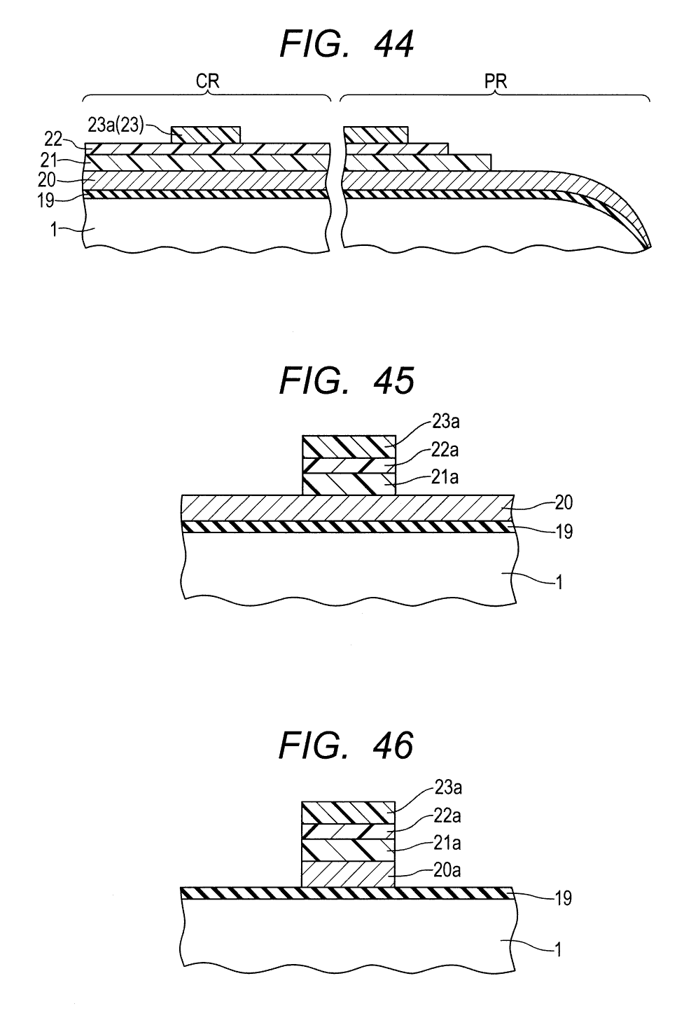

Subsequently, a tri-layer resist system is applied as a photolithographic process for patterning gate electrodes. That is, processes similar to a series of tri-layer resist systemes shown in FIGS. 1 to 20 are applied, and as shown in FIG. 44, the bottom-layer resist film 21, middle-layer resist film 22 and top-layer resist film 23 are formed. In the chip formation region CR in the semiconductor substrate 1, the resist pattern 23a of the top-layer resist film 23 for patterning the gate electrode is formed. In contrast, in the outer periphery PR in the semiconductor substrate 1, the middle-layer resist film 22 and bottom-layer resist film 21 on which humps are crushed and flattened by spraying the fluid at a high pressure are appeared.

Subsequently, etching is performed on the middle-layer resist film 22 using as a mask the resist pattern 23a of the top-layer resist film 23, whereby the resist pattern 23a is transferred onto the middle-layer resist film 22 as a resist pattern 22a. Furthermore, etching is performed on the bottom-layer resist film 21 using the resist pattern 22a of the middle-layer resist film 22 as a mask, whereby the resist pattern 23a is transferred onto the bottom-layer resist film 21 as a resist pattern 21a.

In such a manner, as shown in FIG. 45, the resist patterns 23a, 22a, 21a by the bottom-layer resist film, middle-layer resist film and top-layer resist film for patterning the gate electrode are formed. FIG. 45 shows the state that the resist patterns 21a through 23a of the top-layer resist film 23 are left, but not all the resist patterns needs not be left as long as at least the resist pattern 21a in the bottom-layer resist film 21 is left.

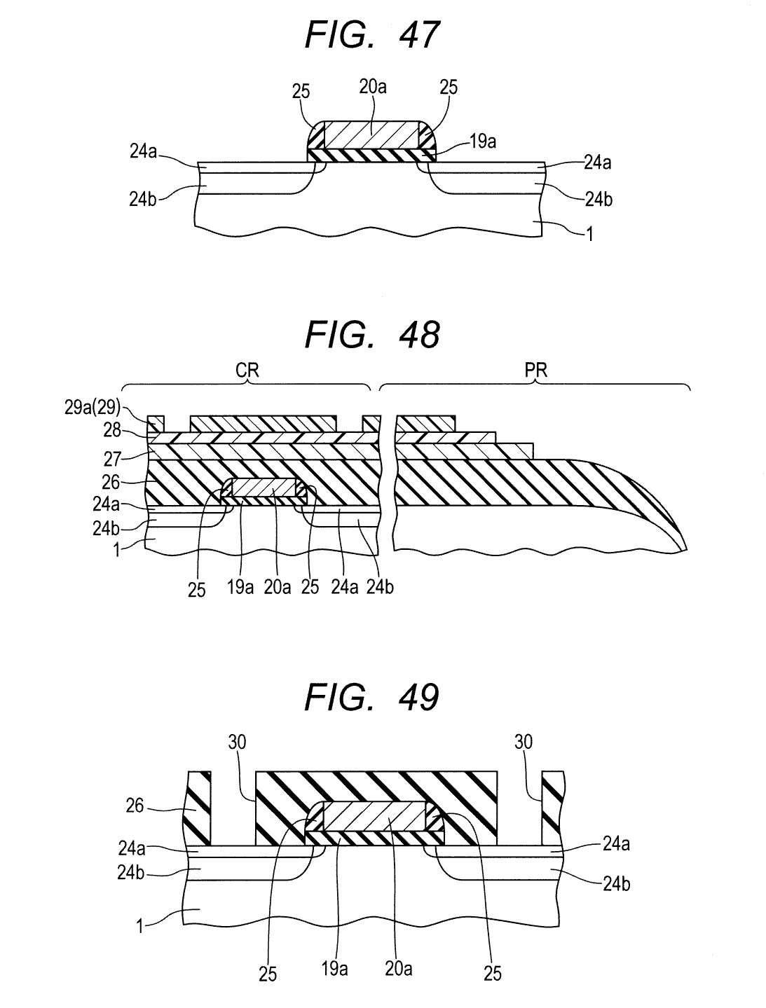

Subsequently, as shown in FIG. 46, a gate electrode 20a is formed by performing etching on the conductive film 20 using the resist patterns 23a, 22a, 21a as masks. Subsequently, an n-type low-concentration impurity region 24a is formed by injecting, for example, a low dose of n-type impurities on the semiconductor substrate 1 using the gate electrode 20a as a mask (refer to FIG. 47). Subsequently, an insulation film (not shown) is formed in a manner of covering the gate electrode 20a. A side wall insulation film 25 is formed on the side wall of the gate electrode 20a by performing anisotropic etching on the insulation film (refer to FIG. 47).

Subsequently, an n-type high-concentration impurity region 24b is formed by injecting a high dose of n-type impurities using the gate electrode 20a and side wall insulation film 25 as masks. In such a manner, as shown in FIG. 47, a MOS (Metal Oxide Semiconductor) transistor including the gate electrode 20a, n-type low-concentration impurity region 24a and n-type high-concentration impurity region 24b formed with the gate insulating film 19a interposed therebetween is formed on the surface of the semiconductor substrate 1. Subsequently, an interlayer insulator 26 such as a silicon oxide film is formed on the substrate 1 in a manner of covering the gate electrode 20a and the like (refer to FIG. 48).

Subsequently, a tri-layer resist system is applied as a photolithographic process for forming a contact hole in the interlayer insulator 26. That is, processes similar to a series of the tri-layer resist systemes shown in FIGS. 1 to 20 are applied, and as shown in FIG. 48, the bottom-layer resist film 27, middle-layer resist film 28 and top-layer resist film 29 are formed. In the chip formation region CR in the semiconductor substrate 1, a resist pattern 29a of the top-layer resist film 29 for forming the contact hole is formed. In contrast, in the outer periphery PR in the semiconductor substrate 1, the middle-layer resist film 28 and bottom-layer resist film 27 on which the hump is crushed and flattened by spraying the fluid at a high pressure are appeared.

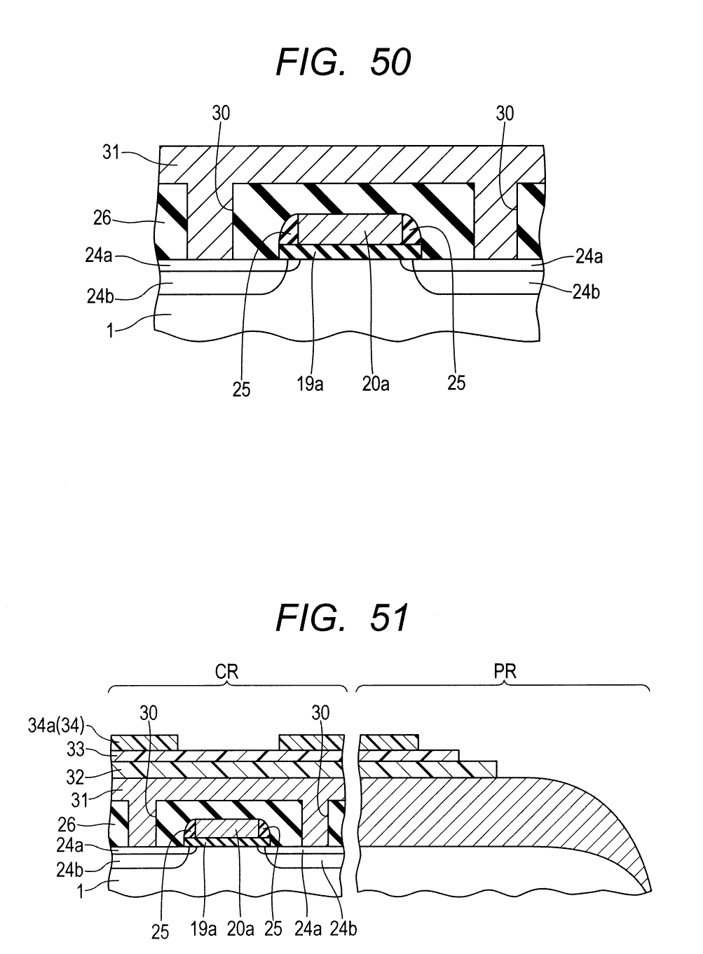

Subsequently, the resist pattern 29a of the top-layer resist film 29 is transferred onto the middle-layer resist film 28 and bottom-layer resist film 27 so that a resist pattern (not shown) for forming the contact hole is formed. As shown in FIG. 49, a contact hole 30 appeared on the surface of the n-type high-concentration impurity region 24b, is formed by performing anisotropic etching on the interlayer insulator 26 by using the resist pattern as a mask. Thereafter, the resist pattern is removed. Subsequently, as shown in FIG. 50, a predetermined conductive film 31 containing a barrier metal and the like are formed on the interlayer insulator 26 in a manner of filling the contact hole.

Subsequently, a tri-layer resist system is applied as a photolithographic process for patterning the conductive film 31. That is, processes similar to a series of tri-layer resist systemes shown in FIGS. 1 to 20 are applied, and as shown in FIG. 51, the bottom-layer resist film 32, middle-layer resist film 33 and top-layer resist film 34 are formed. In the chip formation region CR in the semiconductor substrate 1, a resist pattern 34a of the top-layer resist film 34 for patterning the conductive film 31 is formed. Meanwhile, at the outer periphery PR in the semiconductor substrate 1, the middle-layer resist film 33 and bottom-layer resist film 32 on which the hump is crushed and flattened by spraying the fluid at a high pressure are appeared.

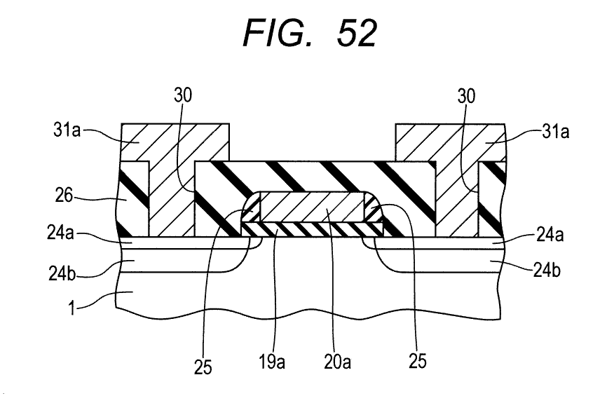

The resist pattern 34a of the top-layer resist film 34 is transferred onto the middle-layer resist film 33 and bottom-layer resist film 32, forming a conductive film for patterning the resist pattern (not shown). As shown in FIG. 52, a wiring 31a which is electrically connected to the n-type high-concentration impurity region 24b is formed by performing anisotropic etching on the conductive film 31 by using the resist pattern as a mask. Thereafter, the bottom-layer resist film 32 and the like are removed. In such a manner, a principal part of the semiconductor device having a transistor is formed.

In the method of manufacturing a semiconductor device employing the tri-layer resist system as the photolithographic process mentioned above, humps generated in the bottom-layer resist film or middle-layer resist film at the outer periphery of the semiconductor substrate 1 are crushed and flattened by spraying a liquid at a high pressure. Accordingly, resist residues or residues of the films to be processed are reduced at the outer periphery of the semiconductor substrate 1 after the films to be processed such as the conductive film 20, interlayer insulator 26 and conductive film 31 are patterned. This results in the suppression of a lowered yield of the semiconductor device caused by the generation of foreign substances, and suppression of lowered reliability of the semiconductor device caused by peeling of the films.

It should be noted that the tri-layer resist system mentioned above is not limited to the step described in First Embodiment or Third Embodiment, and is be widely applicable to steps in which the photolithographic process is performed. Moreover, the photolithographic process is not limited to the tri-layer resist system, and is also applicable to a bi-layer resist process and resist processes involving four or more layers as long as the process includes transferring the resist pattern transferred onto the photosensitive resist onto the resist film having etching resistance in relation with the etching of the processed film.

The embodiments disclosed herein are mere examples, and the present invention is not limited to these embodiments. The present invention is defined not in the scope described above but in the claims, and shall encompass all modifications having the meanings defined in claims and within scope which is equivalent to the claims.

The present invention is effectively used for a method of manufacturing a semiconductor device applying a multilayer resist system and the like.

What is claimed is:

1. A method of manufacturing a semiconductor device comprising the steps of:
forming a processed film which is subjected to a predetermined process over a main face of a semiconductor substrate;
forming a first resist film which serves as a mask material when the processed film is processed in a manner of covering the processed film;
forming a second resist film for performing patterning using the first resist film as a mask material in a manner of covering the first resist film;
forming a predetermined resist pattern by performing a predetermined photolithographic process and a development process on the second resist film;
forming the mask material by etching the first resist film by using the resist pattern as a mask; and
performing a predetermined process on the processed film by using the mask material as a mask, wherein the step of forming the first resist film comprises the steps of:
forming a resist material film by applying a predetermined resist material having etching resistance to processing of the processed film onto the surface of the processed film;
removing a portion of the resist material film positioned at the outer periphery by spraying the outer periphery of the semiconductor substrate with an organic solvent while spinning the semiconductor substrate;
drying the semiconductor substrate with the portion of the resist material positioned at the outer periphery removed therefrom;
spraying the outer periphery of the resist material film left over the semiconductor substrate with at least one fluid selected from predetermined liquids and gases for crushing the resist material film while spinning the semiconductor substrate; and
performing a heat treatment on the resist material film.

2. The method of manufacturing a semiconductor device according to claim 1, wherein the fluid is an inactive liquid.

3. The method of manufacturing a semiconductor device according to claim 1, wherein the fluid is an inactive gas.

4. The method of manufacturing a semiconductor device according to claim 1, wherein the fluid is a solvent mixture of a solvent having a relatively high solubility and a solvent having a relatively low solubility.

5. The method of manufacturing a semiconductor device according to claim 1 wherein the fluid is an ozone-containing gas or ozone water.

6. The method of manufacturing a semiconductor device according to claim 1, wherein the fluid contains inactive solid minute particles.

7. The method of manufacturing a semiconductor device according to any one of claims 1 to 5, wherein in the step of spraying the fluid, the fluid is sprayed by being heated to a predetermined temperature.

8. The method of manufacturing a semiconductor device according to any one of claims 1 to 7, wherein in the step of spraying the fluid, the fluid is sprayed in a state that the semiconductor substrate is heated to soften the first resist film.

9. The method of manufacturing a semiconductor device according to any one of claims 1 to 8,
wherein the step of forming the first resist film comprises the step of forming a plurality of layers of resist films, and
wherein the step of forming the second resist film comprises the step of forming a resist material film containing a photosensitive material over the surface of the first resist film.

10. A semiconductor device manufactured by the method of manufacturing a semiconductor device according to any one of claims 1 to 9.

11. A resist coater comprising:
a spin chuck which rotatably retains a semiconductor substrate;
a fluid feed section which serves as a source of a predetermined fluid for crushing the resist material film formed over the surface of the semiconductor substrate; and
a fluid discharge nozzle which is coupled to the fluid feed section, and discharges and sprays the predetermined fluid toward a portion positioned at the outer periphery of the semiconductor substrate in the resist material film formed over the surface of the semiconductor substrate in a state that the semiconductor substrate is retained on the spin chuck.

12. The resist coater according to claim 11, comprising a first heater for heating the semiconductor substrate retained on the spin chuck.

13. The resist coater according to claim 11 or 12, comprising a second heater for heating a fluid sprayed from the fluid discharge nozzle.
